(19) United States
(12) Patent Application Publication
(10) Pub. No.: US 2007/0284715 A1
(43) Pub. Date: Dec. 13, 2007

(54) System-in-package device

(75) Inventors: Wen Feng Li, Zihquan Township (TW); Yi Chuan Ding, Kaohsiung City (TW)

Correspondence Address: REED SMITH LLP;Suite 1400, 3110 Fairview Park Drive, Falls Church, VA, 22042, US

(73) Assignee: Advanced Semiconductor Engineering, Inc.

(21) Appl. No.: 11/651,082

(22) Filed: Jan. 9, 2007

(30) Foreign Application Priority Data
Jun. 7, 2006 (TW) 095120168

(51) Int. Cl. H01L 23/02

(52) U.S. Cl. 257/686

(57) ABSTRACT

A system-in-package (SIP) device includes a substrate, a first chip and a chip package. The first chip is mounted and electrically connected to the substrate. The chip package is disposed above the first chip, and includes a leadframe, a second chip and a first encapsulant. The leadframe includes a die pad and a plurality of leads, wherein each lead is divided into an inner lead and an outer lead, and the outer lead is mounted and electrically connected to the substrate. The second chip is mounted on the die pad and electrically connected to the inner leads. The first encapsulant seals the second chip and a part of the leadframe, and exposes out the outer leads. The SIP device further includes a second encapsulant seals a part of the chip package, the first chip and the upper surface of the substrate, and exposes out the lower surface of the substrate.

### CROSS REFERENCE TO RELATED APPLICATION

This application claims the priority benefit of Taiwan Patent Application Serial Number 095120168, filed Jun. 7, 2006, the full disclosure of which is incorporated herein by reference.

### BACKGROUND OF THE INVENTION

1. Field of the Invention

The present invention generally relates to a system-in-package (SIP) device, and more particularly to a system-in-package (SIP) device, wherein leads of the leadframe of the chip package are directly mounted and electrically connected to the substrate of the SIP device.

2. Description of the Related Art

Currently, a system-in-package (SIP) device is related to a semiconductor package disposed in another semiconductor package. The basic object of the system-in-package (SIP) device is to increase the density of components so as to result in more functions of components per unit volume and better regional efficiency. Thus, the total area of the SIP device can be decreased, and the cost is decreased simultaneously.

Referring to FIG. 1, a conventional system-in-package (SIP) device 10 mainly includes a chip package 30 disposed in the SIP device 10. The chip package 30 includes a substrate 32, a memory chip 34 and an encapsulant 36. The substrate 32 has an upper surface 31 and a lower surface 33 opposite to the upper surface 31. The memory chip 34 is mounted on the lower surface 33 of the substrate 32, and is electrically connected to the substrate 32 by means of a plurality of bonding wires 38. The encapsulant 36 encloses the memory chip 34, the substrate 32 and the bonding wires 38, but exposes out the upper surface 31 of the substrate 32.

The SIP device 10 further includes a substrate 22, a processor chip 24, a spacer 42 and an encapsulant 26. The substrate 22 has an upper surface 21 and a lower surface 23 opposite to the upper surface 21. The processor chip 24 is mounted on the substrate 22, and is electrically connected to the substrate 22 by means of a plurality of bonding wires 28. The spacer 42 is disposed between the processor chip 24 and the encapsulant 36, thereby defining a predetermined gap between the substrate 22 and the encapsulant 36. The heights of bonding wires 28 are less than the predetermined gap. Furthermore, the substrate 22 can be electrically connected to the substrate 32 by means of a plurality of bonding wires 44. The encapsulant 26 encloses the chip package 30, the spacer 42, the bonding wires 28, 44, the processor chip 24 and the upper surface 21 of the substrate 22, and exposes out the lower surface 23 of the substrate 22. The substrate 22 includes a plurality of solder balls 46, which are disposed on the lower surface 23 of the substrate 22.

However, the above-mentioned conventional SIP device is generally constituted by two substrates 22, 32 and has the following disadvantages. First, the bonding wires 44 adapted for electrically connecting the substrate 32 to the substrate 22 are too long, and thus the encapsulant 26 may flush the bonding wires 44 while the encapsulant 26 is formed. The flushed bonding wires 44 may causes SIP device to have a short circuit so as to increase unserviceable products. Second, since the memory chip 34 is mounted on the lower surface 33 of the substrate 32, it is difficult to dissipate the heat from the memory chip 34. Thus, the efficiency of the memory chip 34 can be decreased. Third, the memory chip 34 cannot be directly electrically tested after the memory chip 34 is packaged in the chip package 30. The memory chip 34 can not be electrically tested until the SIP device is finished.

U.S. Pat. No. 6,607,937, entitled “Stacked Microelectronic Dies and Methods for Stacking Microelectronic Dies” discloses an assembly of two packaged microelectronic devices and method for forming the same. The two packaged microelectronic devices are upper and lower packaged devices, and the upper packaged device is stacked on the lower packaged device. The upper packaged device includes a microelectronic chip, which is electrically connected to a plurality of bonding pads of a printed circuit board by means of a plurality of connecting members, e.g. leads or pins. Although the microelectronic chip can be electrically connected to the bonding pads of the printed circuit board by means of general leads or pins, the microelectronic chip of U.S. Pat. No. 6,607,937 is not mounted on a die pad of a leadframe for dissipating the heat from the microelectronic chip.

Accordingly, there exists a need for a system-in-package (SIP) device capable of solving the above-mentioned problems.

### SUMMARY OF THE INVENTION

It is an object of the present invention to provide a system-in-package (SIP) device, wherein leads of the leadframe of the chip package are directly mounted and electrically connected to the substrate of the SIP device.

It is another object of the present invention to provide a system-in-package (SIP) device, wherein both first and second encapsulants expose out the upper surface of the die pad, and the second chip is mounted on the lower surface of the die pad, whereby the heat resulted from the second chip can be directly dissipated to the environment by the die pad.

In order to achieve the foregoing object, the present invention provides a system-in-package (SIP) device including a substrate, a first chip and a chip package. The substrate has an upper surface and a lower surface opposite to the upper surface. The first chip is mounted and electrically connected to the substrate. The chip package is disposed above the first chip, and includes a leadframe, a second chip and a first encapsulant. The leadframe includes a die pad and a plurality of leads, wherein each lead is divided into an inner lead and an outer lead. The outer leads are mounted and electrically connected to the substrate. The second chip is mounted on the die pad and electrically connected to the inner leads. The first encapsulant seals the second chip and a part of the leadframe, and exposes out the outer leads. The SIP device further includes a second encapsulant adapted to seal a part of the chip package, the first chip and the upper surface of the substrate, and to expose out the lower surface of the substrate.

The SIP device of the present invention is characterized in that a general substrate of the chip package is replaced with a leadframe so as to have the following advantages. First, the leads of the leadframe of the chip package are electrically connected to the substrate by using a surface mounting technology (SMT), i.e. the chip package are not electrically connected to the substrate by using a wire bonding technology. Thus, the second encapsulant will not flush the leads of the leadframe of the chip package while the second encapsulant is formed. Second, it is easy to rework that the leads of the leadframe of the chip package are electrically connected to the substrate by using a surface mounting technology (SMT), and oppositely it is difficult to rework that the chip package are electrically connected to the substrate by using a wire bonding technology. Thus, the present invention can decrease the lost yield. Third, compared with the prior art, the electrical test of the second chip of the present invention is not required to wait for the SIP device which is finished, i.e. the second chip can be directly electrically tested after the second chip is packaged in the chip package. Thus, the unserviceable second chip can be sieved out in advance so as to decrease the lost yield of the whole SIP device.

The foregoing, as well as additional objects, features and advantages of the invention will be more apparent from the following detailed description, which proceeds with reference to the accompanying drawings.

### BRIEF DESCRIPTION OF THE DRAWINGS

FIG. 1 is a sectional schematic view of a system-in-package (SIP) device in the prior art.

FIG. 2a is a sectional schematic view of a system-in-package (SIP) device according to the first embodiment of the present invention.

FIG. 2b is a sectional schematic view of a system-in-package (SIP) device according to an alternative embodiment of the present invention.

FIG. 3 is a sectional schematic view of a system-in-package (SIP) device according to the second embodiment of the present invention.

FIG. 4 is a sectional schematic view of a system-in-package (SIP) device according to the third embodiment of the present invention.

### DETAILED DESCRIPTION OF THE PREFERRED EMBODIMENTS

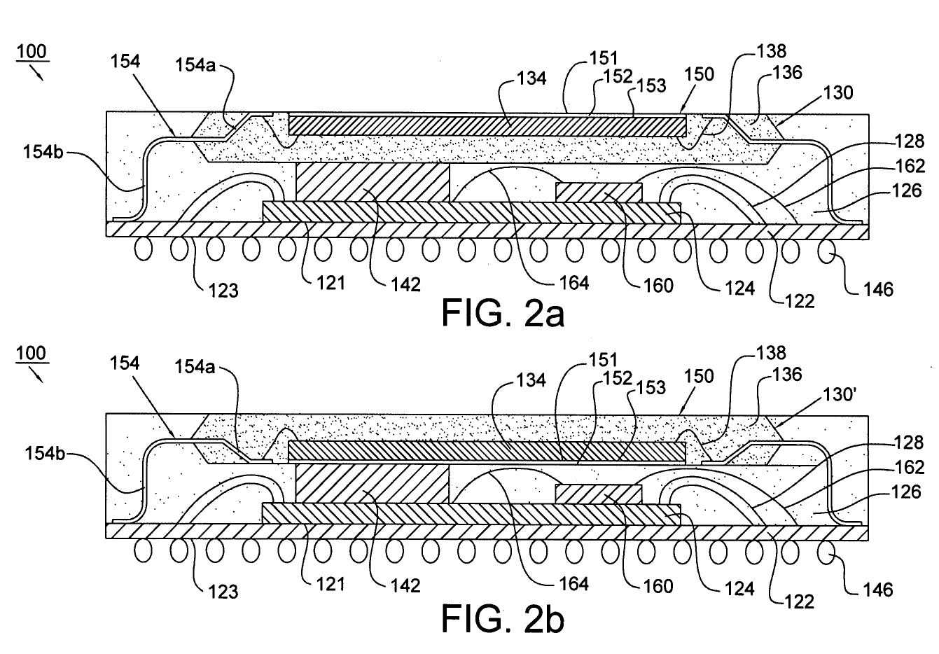

Referring to FIG. 2a, it depicts a system-in-package (SIP) device 100 according to the first embodiment of the present invention. The SIP device 100 includes a chip package 130, which includes a leadframe 150, a second chip 134 and an encapsulant 136. The leadframe 150 includes a die pad 152 and a plurality of leads 154. Each lead 154 is divided into an inner lead 154a and an outer lead 154b. The die pad 152 and a plurality of leads 154 can be integrally formed. The die pad 152 has an upper surface 151 and a lower surface 153, the upper surface 151 orients against a substrate 122, and the lower surface 153 is opposite to the upper surface 151. The second chip 134, e.g. memory chip, is mounted on the lower surface 153 of the die pad 152 and electrically connected to the inner leads 154a by means of a plurality of bonding wires 138. The encapsulant 136 seals the second chip 134, the bonding wires 138, the lower surface 153 of the die pad 152 and the inner leads 154a, and exposes out the upper surface 151 of the die pad 152 and the outer leads 154b. Since the encapsulant 136 exposes out the upper surface 151 of the die pad 152 and the second chip 134 is mounted on the lower surface 153 of the die pad 152, the heat resulted from the second chip 134 can be dissipated by the die pad 152.

The SIP device 100 further includes the substrate 122, a first chip 124 and an encapsulant 126. The substrate 122 has an upper surface 121 and a lower surface 123 opposite to the upper surface 121. The first chip 124, e.g. processor chip, is mounted on the upper surface 121 of the substrate 122, and is electrically connected to the substrate 122 by means of a plurality of bonding wires 128. The chip package 130 is stacked above the first chip 124.

The SIP device 100 further includes a spacer 142, which is disposed between the first chip 124 and the chip package 130, thereby defining a first predetermined gap between the substrate 122 and the encapsulant 136. The heights of the bonding wires 128 are less than the first predetermined gap. Furthermore, the outer leads 154b of the leadframe 150 of the chip package 130 are mounted and electrically connected to the substrate 122 of the SIP device 100. The encapsulant 126 seals a part of the chip package 130 (which includes the outer leads 154b), the spacer 142, the bonding wires 128, the first chip 124 and the upper surface 121 of the substrate 122, and to expose out the lower surface 123 of the substrate 122 and the upper surface 151 of the die pad 152. Since the encapsulant 126 also exposes out the upper surface 151 of the die pad 152, the heat resulted from the second chip 134 can be directly dissipated to the environment by the die pad 152. It is apparent to one of ordinary skill in the art that the die pad 152 can be replaced by any type of heat sink, or a heat sink (not shown) is additionally assembled on the upper surface 151 of the die pad 152 so as to increase the efficiency of heat dissipation.

Referring to FIG. 2b, it depicts a chip package 130′ of a system-in-package (SIP) device 100 according to an alternative embodiment of the present invention. The die pad 152 has an upper surface 151 and a lower surface 153, the upper surface 151 orients against a substrate 122, and the lower surface 153 is opposite to the upper surface 151. The second chip 134 is mounted on the upper surface 151 of the die pad 152 and electrically connected to the inner leads 154a by means of a plurality of bonding wires 138. The encapsulant 136 seals the second chip 134, the bonding wires 138, the upper surface 151 and the lower surface 153 of the die pad 152 and the inner leads 154a, and to expose out the outer leads 154b.

In addition, the substrate 122 includes a plurality of electrical contacts 146, e.g. solder balls, are disposed the lower surface 123 of the substrate 122, and are adapted to electrically connected to an external electronic device (not shown) or an external circuit board (not shown).

Referring to FIGS. 2a and 2b again, the SIP device 100 further includes a third chip 160, which is stacked on the first chip 124. The SIP device 100 further includes a plurality of bonding wires 162 adapted for electrically connecting the third chip 160 to the substrate 122. The heights of the bonding wires 162 are less than the first predetermined gap. Furthermore, the spacer 142 of the SIP device 100 is further adapted to define a second predetermined gap between the first chip 124 and the encapsulant 136. The SIP device 100 further includes a plurality of bonding wires 164 adapted for electrically connecting the third chip 160 to the first chip 124. The heights of the bonding wires 164 are less than the second predetermined gap.

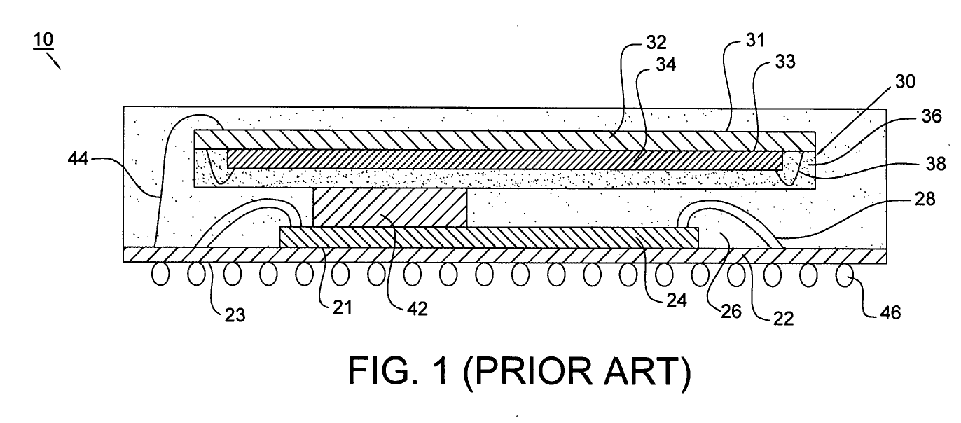

The SIP device of the present invention is characterized in that a general substrate (e.g. the substrate 32 shown in FIG. 1) of the chip package is replaced with a leadframe so as to have the following advantages. First, the leads of the leadframe of the chip package are electrically connected to the substrate by means of a surface mounting technology (SMT), i.e. the chip package are not electrically connected to the substrate by means of a wire bonding technology. Thus, it is not easy that the encapsulant 126 flushes the leads of the leadframe of the chip package while the encapsulant 126 is formed. Second, it is easy to rework that the leads of the leadframe of the chip package are electrically connected to the substrate by using a surface mounting technology (SMT), and oppositely it is difficult to rework that the chip package are electrically connected to the substrate by using a wire bonding technology. Thus, the present invention can decrease the lost yield. Third, since both encapsulants 126, 136 expose out the upper surface of the die pad and the second chip is mounted on the lower surface of the die pad, the heat resulted from the second chip can be directly dissipated to the environment by the die pad, thereby decrease the work temperature of the second chip and not decrease the efficiency of the second chip. Fourth, compared with the prior art, the electrical test of the second chip of the present invention is not required to wait for the SIP device which is finished, i.e. the second chip can be directly electrically tested after the second chip is packaged in the chip package. Thus, the unserviceable second chip can be sieved out in advance so as to decrease the lost yield of the whole SIP device.

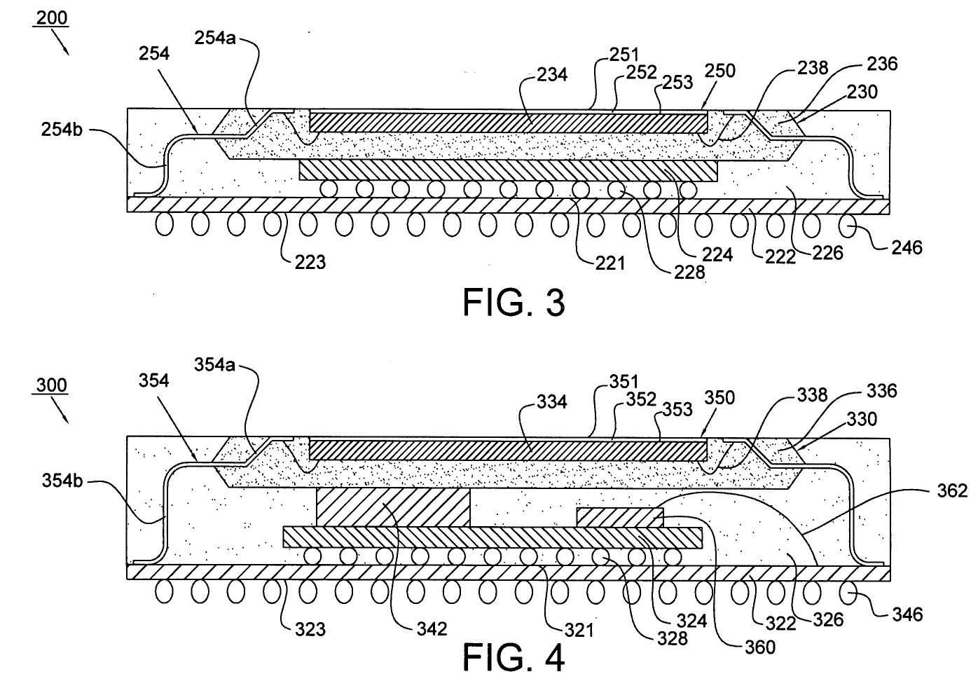

Referring to FIG. 3, it depicts a system-in-package (SIP) device 200 according to the second embodiment of the present invention. The SIP device 200 includes a chip package 230, which includes a leadframe 250, a second chip 234 and an encapsulant 236. The leadframe 250 includes a die pad 252 and a plurality of leads 254. Each lead 254 is divided into an inner lead 254a and an outer lead 254b. The die pad 252 has an upper surface 251 and a lower surface 253, the upper surface 251 orients against a substrate 222, and the lower surface 253 is opposite to the upper surface 251. The second chip 234, e.g. memory chip, is mounted on the lower surface 253 of the die pad 252 and electrically connected to the inner leads 254a by means of a plurality of bonding wires 238. The encapsulant 236 seals the second chip 234, the bonding wires 238, the lower surface 253 of the die pad 252 and the inner leads 154a, and exposes out the upper surface 251 of the die pad 252 and the outer leads 254b.

The SIP device 200 further includes the substrate 222, a first chip 224 and an encapsulant 226. The substrate 222 has an upper surface 221 and a lower surface 223 opposite to the upper surface 221. The first chip 224, e.g. processor chip, is mounted on the substrate 222, and is electrically connected to the substrate 222 by means of a plurality of metallic bumps 228. The chip package 230 is stacked above the first chip 224. Furthermore, the outer leads 254b of the leadframe 250 of the chip package 230 are mounted and electrically connected to the substrate 222 of the SIP device 200. The encapsulant 226 seals a part of the chip package 230 (which includes the outer leads 254b), the first chip 224 and the upper surface 221 of the substrate 222, and exposes out the lower surface 223 of the substrate 222 and the upper surface 251 of the die pad 252. The substrate 222 includes a plurality of electrical contacts 246, e.g. solder balls, are disposed the lower surface 223 of the substrate 222 and are adapted to electrically connected to an external electronic device (not shown) or an external circuit board (not shown).

Referring to FIG. 4, it depicts a system-in-package (SIP) device 300 according to the third embodiment of the present invention. The SIP device 300 in the third embodiment is substantially similar to the SIP device 200 in the second embodiment, wherein the similar elements are designated with the similar reference numerals. The SIP device 300 further. includes a third chip 360, which is stacked on the first chip 324. The SIP device 300 further includes a spacer 342, which is disposed between the first chip 324 and the chip package 330, thereby defining a predetermined gap between the substrate 322 and the encapsulant 336. The SIP device 300 further includes a plurality of bonding wires 362 adapted for electrically connecting the third chip 360 to the substrate 322. The heights of the bonding wires 362 are less than the predetermined gap.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A system-in-package device comprising:
a substrate having an upper surface and a lower surface opposite to the upper surface;
a first chip mounted and electrically connected to the substrate;
a chip package disposed above the first chip and comprising:
a leadframe comprising a die pad and a plurality of leads, wherein each lead comprises an inner lead and an outer lead, and the outer lead is mounted and electrically connected to the substrate;
a second chip mounted on the die pad and electrically connected to the inner leads; and
a first encapsulant adapted to seal the second chip and a part of the leadframe, and to expose out the outer leads; and
a second encapsulant adapted to seal a part of the chip package, the first chip and the upper surface of the substrate, and to expose out the lower surface of the substrate.

2. The system-in-package device as claimed in claim 1, further comprising:
a spacer disposed between the first chip and the chip package, thereby defining a first predetermined gap between the substrate and the first encapsulant, and a second predetermined gap between the first chip and the first encapsulant.

3. The system-in-package device as claimed in claim 2, further comprising:
a plurality of first bonding wires adapted for electrically connecting the first chip to the substrate, wherein the heights of the first bonding wires are less than the first predetermined gap.

4. The system-in-package device as claimed in claim 2, further comprising:
a third chip stacked on the first chip.

5. The system-in-package device as claimed in claim 4, further comprising:
a plurality of second bonding wires adapted for electrically connecting the third chip to the substrate, wherein the heights of the second bonding wires are less than the first predetermined gap.

6. The system-in-package device as claimed in claim 4, further comprising:
a plurality of third bonding wires adapted for electrically connecting the third chip to the first chip, wherein the heights of the third bonding wires are less than the second predetermined gap.

7. The system-in-package device as claimed in claim 1, further comprising:
a plurality of metallic bumps adapted for electrically connecting the first chip to the substrate.

8. The system-in-package device as claimed in claim 7, further comprising:
a spacer disposed between the first chip and the chip package, thereby defining a predetermined gap between the substrate and the first encapsulant.

9. The system-in-package device as claimed in claim 8, further comprising:
a third chip stacked on the first chip.

10. The system-in-package device as claimed in claim 9, further comprising:
a plurality of bonding wires adapted for electrically connecting the third chip to the substrate, wherein the heights of the bonding wires are less than the predetermined gap.

11. The system-in-package device as claimed in claim 1, wherein the substrate comprises a plurality of electrical contacts disposed the lower surface of the substrate.

12. The system-in-package device as claimed in claim 1, wherein the die pad has an upper surface and a lower surface, the upper surface orients against the substrate, the lower surface is opposite to the upper surface, the second chip is mounted on the lower surface of the die pad, and both first and second encapsulants expose out the upper surface of the die pad.

13. The system-in-package device as claimed in claim 1, wherein the die pad has an upper surface and a lower surface, the upper surface orients against the substrate, the lower surface is opposite to the upper surface, and the second chip is mounted on the upper surface of the die pad.

14. A system-in-package device comprising:
a substrate;
a first chip mounted-on the substrate;
at least one first wire electrically connecting the first chip to the substrate;
a spacer disposed on the first chip;
a chip package disposed on the spacer, and the chip package comprising:
a leadframe comprising a die pad and a plurality of leads, wherein each lead comprises an inner lead and an outer lead, and the outer lead is mounted and electrically connected to the substrate;
a second chip mounted on the die pad and electrically connected to the inner leads; and
a first encapsulant sealing the second chip and the inner leads of the leadframe; and
a second encapsulant sealing the chip package, the first chip and the substrate,
wherein the first encapsulant and the second encapsulant expose a surface of the leadframe.

15. The system-in-package device as claimed in claim 14, further comprising:
a third chip stacked on the first chip; and
at least one second wire electrically connecting the third chip to the substrate.

16. The system-in-package device as claimed in claim 15, further comprising:
at lest one third wire electrically connecting the third chip to the first chip.

17. A system-in-package device comprising:
a substrate;
a first chip mounted on the substrate;
at least one bump disposed between the first chip and the substrate, and electrically connecting the first chip to the substrate;
a chip package disposed on the first chip, and the chip package comprising:
a leadframe comprising a die pad and a plurality of leads, wherein each lead comprises an inner lead and an outer lead, and the outer lead is mounted and electrically connected to the substrate;
a second chip mounted on the die pad and electrically connected to the inner leads; and
a first encapsulant sealing the second chip and the inner leads of the leadframe; and
a second encapsulant sealing the chip package, the first chip and the substrate,
wherein the first encapsulant and the second encapsulant expose a surface of the leadframe.

18. The system-in-package device as claimed in claim 17, further comprising:
a spacer disposed between the first chip and the chip package; and
a third chip stacked on the first chip.

19. The system-in-package device as claimed in claim 18, further comprising:
at least one second wire electrically connecting the third chip to the substrate.
